(19) United States
(12) Patent Application Publication
(10) Pub. No.: US 2026/0113882 A1
(43) Pub. Date: Apr. 23, 2026

(54) COOLANT DISTRIBUTION UNIT CONTROL SYSTEM

(71) Applicant: LTI Holdings, Inc., Pleasanton, CA (US)

(72) Inventors: John R. Durbin, Spotsylvania, VA (US); Sukhvinder Kang, Pleasanton, CA (US)

(21) Appl. No.: 19/361,905

(22) Filed: Oct. 17, 2025

Related U.S. Application Data
(60) Provisional application No. 63/709,257, filed on Oct. 18, 2024.

(51) Int. Cl. H05K 7/20

(52) U.S. Cl. CPC H05K 7/20281; H05K 7/20272

(57) ABSTRACT

A coolant distribution unit (“CDU”) and method of operating a component of a CDU includes detecting, based on a first sensor information from a first sensor of a plurality of sensors of the CDU, a fault of a component; receiving, from a second sensor of the plurality of sensors, a second sensor information corresponding to the component; verifying, based on the second sensor information, whether the fault is valid; and continuing an operation of the component, in response to determining that the fault is not valid.

### CROSS-REFERENCE TO RELATED APPLICATIONS

This application claims priority to co-pending U.S. Provisional Patent Application No. 63/709,257, filed October 18, 2024, the entire content of which is incorporated herein by reference.

### SUMMARY

Computer system/data centers employ various cooling/heat dissipation methods to maintain environmental conditions suitable for information technology (IT) equipment (for example, servers, network switches, routers, storage devices, and other computing hardware) operation. Some data centers may utilize a liquid cooling system, where a liquid coolant is used to absorb heat generated from high-power equipment.

Liquid cooling systems include one or more coolant distribution units (CDUs) configured to actively distribute the liquid coolant to the various components of within the data center. CDUs include a primary flow loop/circuit configured to provide liquid coolant to a heat absorbing side of a heat exchanging technology (for example, a liquid-to-liquid heat exchanger) positioned within or outside of the CDU itself and a secondary flow loop/circuit configured to receive heated (“used”) liquid coolant at a heat dissipation side of the heat exchanging technology and return cooled liquid coolant to an equipment liquid cooling network. Within the cooling network of the secondary flow circuit, the liquid coolant is provided to a cooling module (for example, a single or series of cooling plates or heatsinks) proximate or within the information technology equipment via one or more feed lines, through which the liquid coolant absorbs heat from the equipment. The heated liquid coolant then flows, via one or more return feedlines, through a heat dissipating side of the heat exchanging technology within or outside the CDU, dissipating the heat from the liquid coolant. The cooled liquid coolant is then recirculated back to the information technology equipment via the one of more feed lines.

Within the primary flow loop, the used liquid coolant from the heat exchanging technology is cooled via one or more secondary cooling methods (for example, a chiller, cooling towers, etc.). The cooled liquid coolant is then recirculated back through the heat dissipation side of the heat exchanging technology.

CDUs operate through a pump system that circulates the liquid coolant through a network of pipes or channels. CDUs integrate additional components such as valves, filters, and monitoring mechanisms to optimize cooling efficiency and system reliability. Precisely calibrated valves allow for dynamic coolant distribution adjustments tailored to individual equipment/component needs, while filters are employed (for example, within the primary flow circuit) to sieve out impurities and contaminants. Equipped with sensors, CDUs continuously monitor coolant parameters like temperature, flow rate, and pressure levels, enabling real-time interventions to maintain peak thermal performance and reliability in complex environments.

For larger scale data centers, reliable CDU operation may be important for preventing overheating and ensuring performance and longevity of the equipment. Accordingly, embodiments described herein provide various control methods and systems for fault detection and failure mitigation for CDUs.

The present disclosure, therefore, provides, in one aspect, a method of operating a component of a cooling distribution unit (CDU), the method including: detecting, based on a first sensor information from a first sensor of a plurality of sensors of the CDU, a fault of a component; receiving, from a second sensor of the plurality of sensors, a second sensor information corresponding to the component; verifying, based on the second sensor information, whether the fault is valid; and continuing an operation of the component, in response to determining that the fault is not valid.

The present disclosure provides, in another aspect, a method of controlling a coolant distribution unit (CDU), the method including: determining an operating condition of a component of the CDU; determining an expected value for a sensor configured to measure a condition of the component; and comparing the expected value to an actual value measured by the sensor.

The present disclosure provides, in another aspect, a coolant distribution unit including: a fluid coolant flow system including one or more components; a controller configured to control operation of the components; and a first sensor configured to provide a first sensor information based on a first condition of the fluid coolant flow system, a second sensor configured to provide a second sensor information based on a second condition of the fluid coolant flow system, and a third sensor configured to provide a third sensor information based on a third condition of the fluid coolant flow system, wherein the controller is configured to determine a fault of the components based on the first sensor information or the second sensor information, verify, based on another of the first sensor information and the second sensor information, whether the fault is valid, and continue an operation of the components, in response to determining that the fault is not valid, and determine an expected value for the third sensor based on an operating condition of one of the components, and compare the expected value to the third sensor information.

### BRIEF DESCRIPTION OF THE DRAWINGS

FIG. 1A illustrates a coolant distribution unit (CDU), according to some embodiments.

FIG. 1B illustrates the CDU of FIG. 1A, according to some embodiments.

FIG. 2A is a first portion of schematic diagram of the liquid coolant system of the CDU of FIG. 1A, according to some embodiments.

FIG. 2B is a second portion of the schematic diagram of the liquid coolant system of FIG. 2A, according to some embodiments.

FIG. 3 is a block diagram of an electronic controller of the CDU, according to some embodiments.

FIG. 4 illustrates an equipment cooling network and the CDU of FIG. 1A, according to some embodiments.

FIG. 5 is a flowchart of a method for operating a component of the CDU of FIG. 1A implemented by the electronic controller of FIG. 3 in accordance with some embodiments.

FIG. 6 is a flowchart for a method of operating a component of the CDU of FIG. 1A implemented by the electronical controller of FIG. 3 in accordance with some embodiments.

### DETAILED DESCRIPTION

Embodiments described herein relate to a coolant distribution unit (CDU).

Before any embodiments are explained in detail, it is to be understood that the embodiments are not limited in their application to the details of the configuration and arrangement of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software-based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

Relative terminology, such as, for example, “about,” “approximately,” “substantially,” etc., used in connection with a quantity or condition would be understood by those of ordinary skill to be inclusive of the stated value and has the meaning dictated by the context (e.g., the term includes at least the degree of error associated with the measurement accuracy, tolerances [e.g., manufacturing, assembly, use, etc.] associated with the particular value, etc.). Such terminology should also be considered as disclosing the range defined by the absolute values of the two endpoints. For example, the expression “from about 2 to about 4” also discloses the range “from 2 to 4”. The relative terminology may refer to plus or minus a percentage (e.g., 1%, 5%, 10%, or more) of an indicated value.

It should be understood that although certain drawings illustrate hardware and software located within particular devices, these depictions are for illustrative purposes only. Functionality described herein as being performed by one component may be performed by multiple components in a distributed manner. Likewise, functionality performed by multiple components may be consolidated and performed by a single component. In some embodiments, the illustrated components may be combined or divided into separate software, firmware and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable communication links. Similarly, a component described as performing particular functionality may also perform additional functionality not described herein. For example, a device or structure that is “configured” in a certain way is configured in at least that way but may also be configured in ways that are not explicitly listed.

For ease of description, some or all of the example systems presented herein are illustrated with a single exemplar of each of its component parts. Some examples may not describe or illustrate all components of the systems. Other examples may include more or fewer of each of the illustrated components, may combine some components, or may include additional or alternative components.

Other aspects of the embodiments will become apparent by consideration of the detailed description and accompanying drawings.

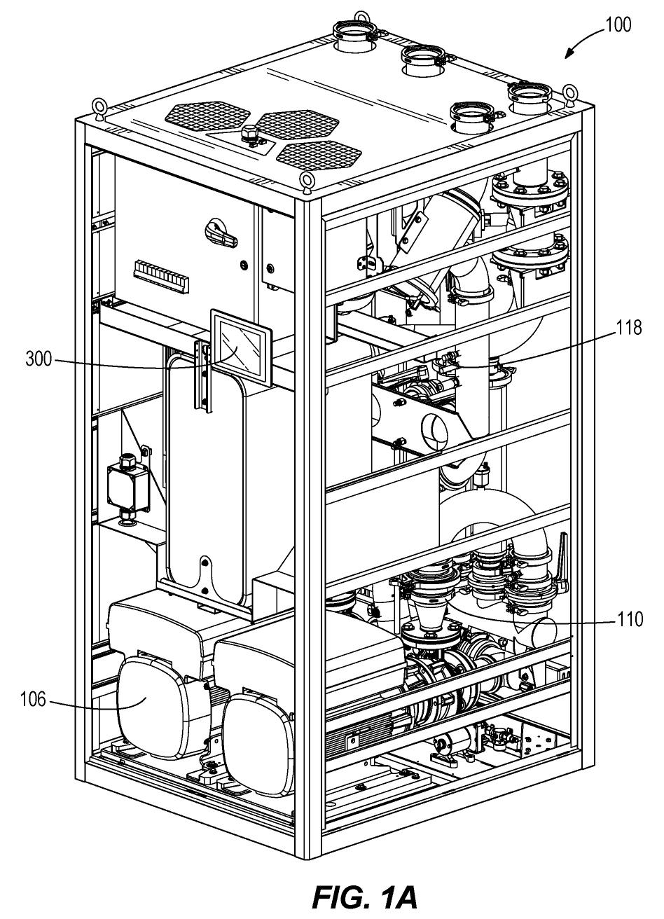

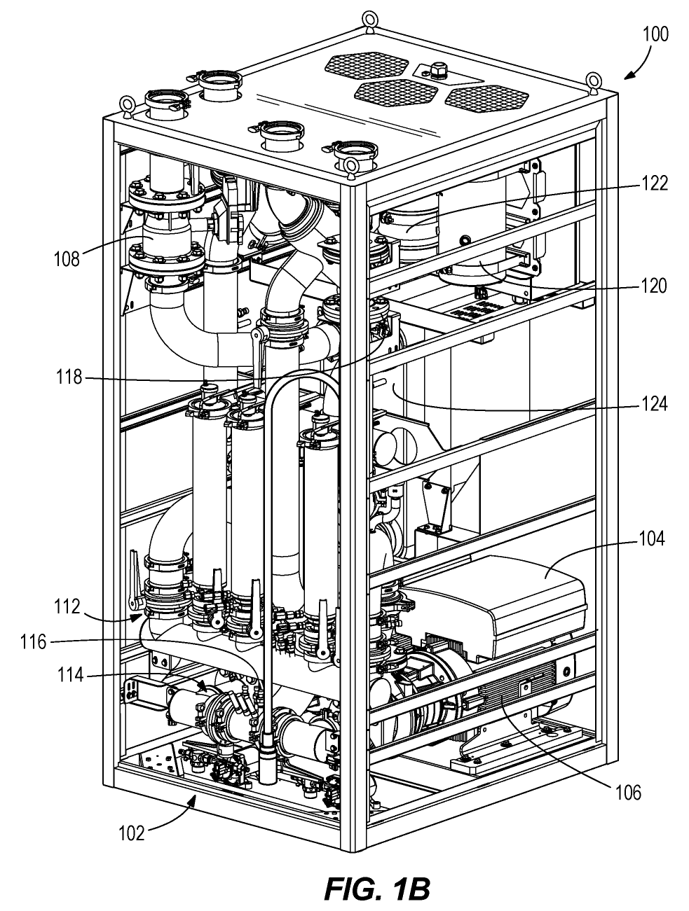

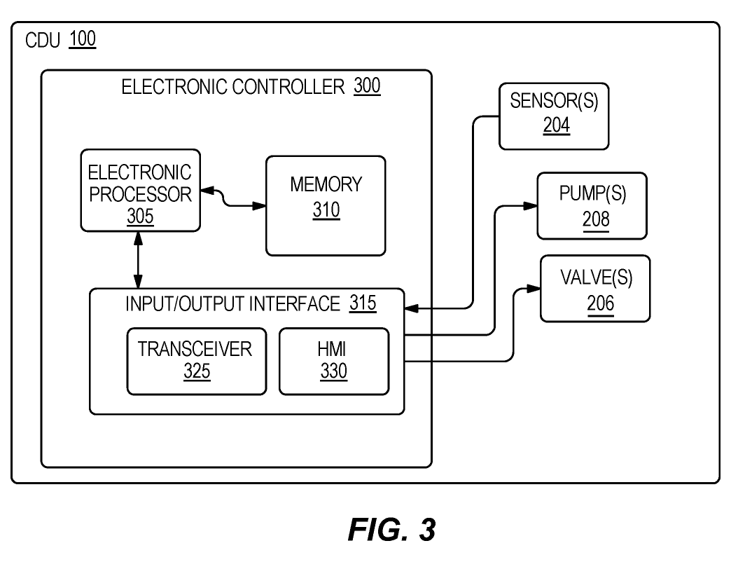

FIGS. 1A and 1B illustrate an example coolant distribution unit (CDU) 100. The CDU 100 includes, among other things, an electronic controller 300 (described in more detail below with respect to FIG. 3), a plurality of pumps (for example, fill and makeup pumps 102, a variable frequency drive (VFD) pump 104, and secondary pumps 106), a plurality of valves (for example, a primary control valve 108, a pump check valve 110, isolation valves 112), and a plurality of sensors (for example, temperature sensors 114, pressure sensors 116, flow meters 118). The CDU 100 also includes a reservoir 120, expansion tanks 122, and a liquid-to-liquid heat exchanger 124. The CDU also includes a housing (not shown).

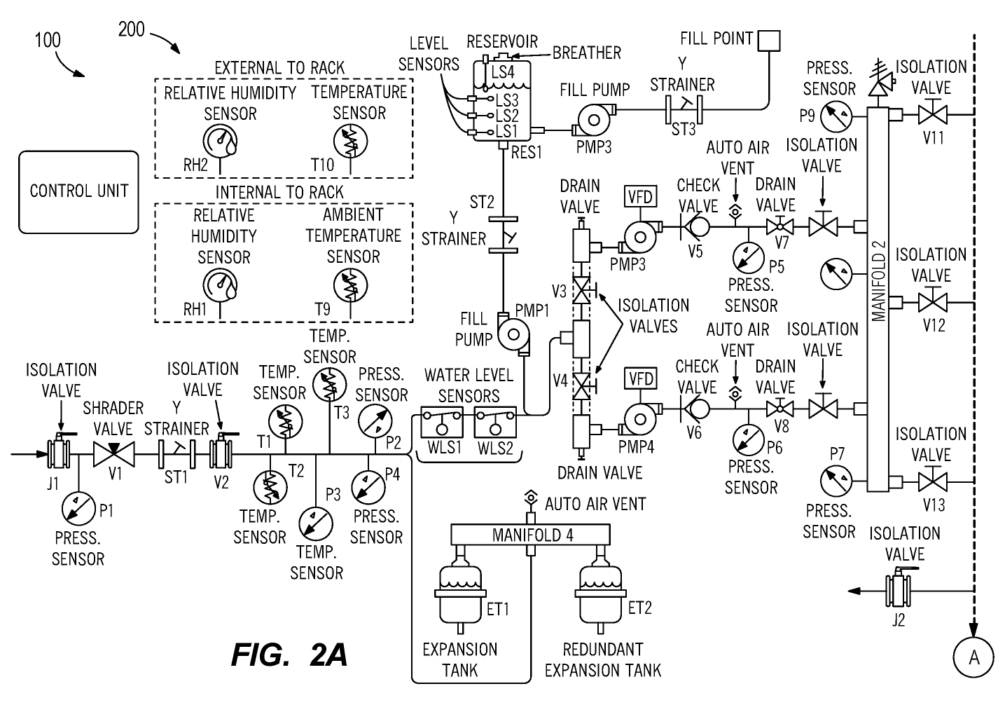

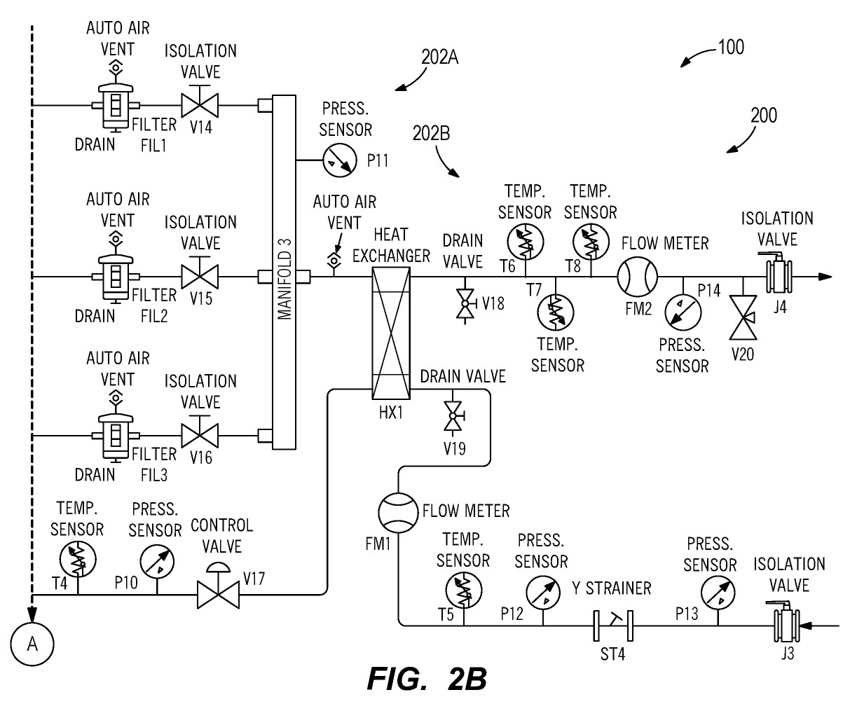

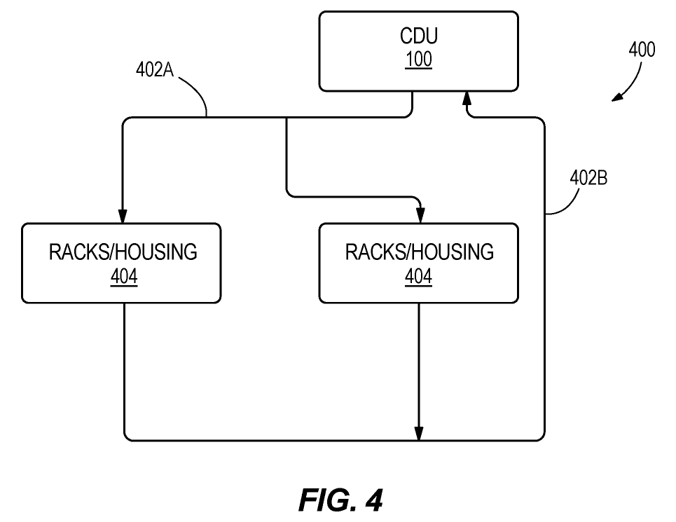

FIGS. 2A - 2B is a schematic diagram illustrating a fluid coolant flow system 200 of the CDU 100 in accordance with some embodiments. The system 200 comprises a primary fluid flow path (referred to herein as primary circuit 202A) of liquid coolant on a first (heat absorption) side of the heat exchanger 124 and a secondary flow path (referred to herein as secondary circuit 202B) of liquid coolant on a second (heat dissipation) side of the heat exchanger 124. The primary circuit 202A includes an input valve J3 and an output valve J2 (isolation valves 112 of FIGS. 1A and 1B). The secondary circuit 202B includes an input valve J1 and an output valve J4 (isolation valves 112 of FIGS. 1A and 1B). The heat exchanger 124 receives cooled liquid coolant from the primary circuit 202A to dissipate heat of the liquid coolant of the secondary circuit 202B received on the heat absorption side of the heat exchanger 124. The cooled liquid coolant of the secondary circuit 202B is then (at valve J4) output (for example, to an equipment coolant network 400, described below with respect to FIG. 4) for providing the recirculated coolant for heat dissipation of one or more information technology (IT) equipment (for example, servers, network switches, routers, storage devices, and other computing hardware). The heated liquid coolant from the network 400 is then returned to the system 200 (at valve J1). Meanwhile, the heated liquid coolant of the primary circuit 202A is recirculated and cooled (for example, via secondary cooling/heat transferring system (not shown) that receives the heated liquid coolant output at valve J2 and provides cooled liquid coolant back to the CDU 100 at the input of valve J3). The CDU 100 may include additional components/subsystems for additional cooling of the liquid coolant in some embodiments.

FIG. 4 is an example equipment cooling network 400 for cooling a plurality of IT equipment in accordance with some embodiments. The equipment cooling network 400 includes a feed line 402A that is configured to receive cooled liquid coolant output from the CDU 100 (i.e. the output of valve J4 of FIG. 2B). The feed line 402A is connected to one or more secondary pipes (not shown) of equipment racks/housing 404, each of the racks/housing 404 including one or more IT equipment. The secondary pipes of the racks/housing 404 may run alongside one or more heat transferring surfaces of the rack/housing 404 (or of the IT equipment itself) to absorb heat generated from the respective IT equipment. From each of the racks/housing 404, the warmed coolant returned to the CDU 100 (at the input of valve J3 of FIG. 2B) via return line 402B to be re-cooled and recirculated within the equipment cooling network 400.

Returning to FIGS. 2A - 2B, as illustrated, the primary circuit 202A includes a plurality of valves V17, V19, J2, and J3 and sensors (for example, temperature sensors T4 and T5, pressure sensors P10, P12, and P13, and flow meter FM1. The secondary circuit 202B also includes a plurality of valves V1 – V16, V18, V20, J1, and J4, pumps PMP1 – PMP4, and sensors (for example, temperature sensors T1 – T3 and T6 – T8, pressure sensors P1 – P9, P11, and P14, and flow meter FM2. The controller 300 is communicatively coupled to and controls operation of each of the plurality of valves V1 – V20, and pumps PMP1 – PMP4 based on sensor information from one or more of the various sensors of the system 200. The controller 300 may also receive sensor information regarding environmental information within the housing of the CDU 100 (for example, via a relative humidity sensor RH1 and an ambient temperature sensor T9) and outside of the housing of the CDU 100 (for example, via a relative humidity sensor RH2 and a temperature sensor T10). For ease of description, the sensors of the flow system 200 are collectively referred to herein as the plurality of sensors 204, the valves of the flow system 200 are collectively referred to herein as the plurality of valves 206, and the pumps of the flow system 200 are collectively referred to herein as the plurality of pumps 208. In some embodiments, one or more different types of sensors of the system 200 (and functionality thereof) may be combined as a single sensor (for example, a combined temperature and humidity sensor, a combined pressure and water flow sensor, and the like). The system 200 may include additional or fewer sensors than those illustrated in FIGS. 2A - 2B.

The fluid coolant flow system 200 may include additional components (for example, filters FIL1 – FIL3, strainers ST1 – ST4, auto air vents, and pressure relief valves) which, for sake of brevity, are not described herein in detail.

FIG. 3 is a block diagram of the electronic controller 300 of the CDU 100 in accordance with some embodiments. The electronic controller 300 includes a plurality of electrical and electronic components that facilitate power, operation control, and protection to the components and modules within the electronic controller 300. The electronic controller 300 includes, among other things, an electronic processor 305 (such as a programmable electronic microprocessor, microcontroller, or similar device), a memory 310 (for example, non-transitory, computer readable memory), and an input/output interface 315. The electronic processor 305 is communicatively connected to the memory 310 and the input/output interface 315. The electronic processor 305, in coordination with the memory 310 and the input/output interface 315, is configured to implement, among other things, the methods described herein. It should be understood that some or all of the components, including additional components, of the controller 300 may be remote/dispersed from each other within the CDU 100 and/or remote from the CDU 100.

The memory 310 may be made up of one or more non-transitory computer-readable media and includes at least a program storage area and a data storage area. The program storage area and the data storage area can include combinations of different types of memory, such as read-only memory (“ROM”), random access memory (“RAM”), flash memory, or other suitable memory devices. The electronic processor 305 is coupled to the memory 310 and the input/output interface 315.

The electronic processor 305 sends and receives information (for example, from the memory 310 and/or the input/output interface 315) and processes the information by executing one or more software instructions or modules, capable of being stored in the memory 310, or another non-transitory computer readable medium. The software can include firmware, one or more applications, program data, filters, rules, one or more program modules, and other executable instructions. The electronic processor 305 is configured to retrieve from the memory 310 and execute, among other things, software for automatic detection/prediction of an anomaly within the CDU 100 and for performing methods as described herein.

In some instances, the electronic controller 300 may be implemented in several independent controllers (for example, programmable electronic controllers) each configured to perform specific functions or sub-functions. For example, one or more components of the controller 300 may be remote from the CDU 100 (for example, part of a remote server, which is not shown, communicatively coupled to the CDU 100). Additionally, the electronic controller 300 may contain sub-modules that include additional electronic processors, memory, or circuits for handling input/output functions, processing of signals, and application of the methods listed below. In other instances, the electronic controller 300 includes additional, fewer, or different components. Thus, the programs may also be distributed among one or more processors.

The input/output interface 315 transmits and receives information from devices external to the electronic controller 300 (for example, over one or more wired and/or wireless connections), for example, components of the CDU 100. The input/output interface 315 receives input (for example, from the plurality of sensors 204), provides system output (for example, to one or more of the plurality of valves 206 and/or the plurality of pumps 208, the transceiver 325 and/or the human machine interface 330 (“HMI”), etc.,). The input/output interface 315 may also include other input and output mechanisms, which for brevity are not described herein and which may be implemented in hardware, software, or a combination of both.

In some instances, the controller 300 further includes the transceiver 325 and/or the HMI 330. The transceiver 325 includes a radio transceiver communicating data over one or more wireless communications networks (for example, cellular networks, satellite networks, land mobile radio networks, etc.). The transceiver 325 also provides wireless communications within the vehicle using suitable network modalities (for example, Bluetooth™, near field communication (NFC), Wi-Fi™, and the like). Accordingly, the transceiver 325 communicatively couples the electronic controller 300 and other components of the CDU 100 with networks or electronic devices both inside and outside the CDU 100. For example, the electronic controller 300, using the transceiver 325, can communicate with a one or more devices (for example, other CDUs 100) over a communications system (not shown) to send and receive data, commands, and other information. The transceiver 325 includes other components that enable wireless communication (for example, amplifiers, antennas, baseband processors, and the like), which for brevity are not described herein and which may be implemented in hardware, software, or a combination of both. Some instances include multiple transceivers or separate transmitting and receiving components (for example, a transmitter and a receiver) instead of a combined transceiver.

The HMI 330 provides visual output, such as, for example, graphical indicators (i.e., fixed or animated icons), lights, colors, text, images, combinations of the foregoing, and the like. The HMI 330 includes a suitable display mechanism for displaying the visual output, such as, for example, an instrument cluster, a center console display screen (for example, a touch screen, or other suitable mechanisms), etc. In some instances, the HMI 330 displays a graphical user interface (GUI) (for example, generated by the electronic processor 305 and presented on a display screen) that enables a driver or passenger to interact with the CDU 100. The HMI 330 may also provide audio output to the driver such as a chime, buzzer, voice output, or other suitable sound through a speaker included in the HMI 330 or separate from the HMI 330. In some instances, HMI 330 provides a combination of visual and audio outputs.

As will be described in further detail below, in some instances the memory 310 includes, among other things, computer executable instructions for component and measurement fault detection and mitigation. In some instances, the computer executable instructions include instructions for training a deep learning system to detect/predict one or more anomalies related to one or more components of the CDU 100.

In some instances, the electronic controller 300 uses one or more machine learning methods (for example, artificial intelligence algorithms) to analyze sensor information from the sensors 204 to identify/predict anomalies within the CDU 100 (as described herein). Machine learning generally refers to the ability of a computer program to learn without being explicitly programmed. In some instances, a computer program (for example, a learning engine) is configured to construct an algorithm based on inputs. Supervised learning involves presenting a computer program with example inputs and their desired outputs. The computer program is configured to learn a general rule that maps the inputs to the outputs from the training data it receives. Example machine learning engines include decision tree learning, association rule learning, artificial neural networks, classifiers, edge computing, inductive logic programming, support vector machines, clustering, Bayesian networks, reinforcement learning, representation learning, similarity and metric learning, sparse dictionary learning, and genetic algorithms. Using these approaches, a computer program can ingest, parse, and understand data and progressively refine algorithms for data analytics.

The system performance of the flow system 200 is dependent on, among other things, proper operation of the pumps 208. In some embodiments, each of the pumps includes a respective pump fault sensor (for example, a fault sensor integrated into the pump). In instances where the pump fault sensor indicates a fault, the sensor is configured to provide a fault signal to the electronic controller 300. The electronic controller 300, in response, may accordingly generate an alert to a user (for example, via the HMI 330), halt or adjust an operation of one or more of the pumps 208, or both. However, there may be instances where the pump fault sensor itself is faulty. In such instances, the pump fault sensor may output the fault signal to the controller 300 even when the respective pump is operating normally. This may result in the controller 300 to provide false alerts and/or unnecessary modifications/shutdowns of one or more operations of the system 200.

Thus, it may be desirable for the electronic controller 300 to perform additional steps to verify whether or not one or more of the pumps are operating properly including evaluating an accuracy of a measurement from one or more of the sensors 204.

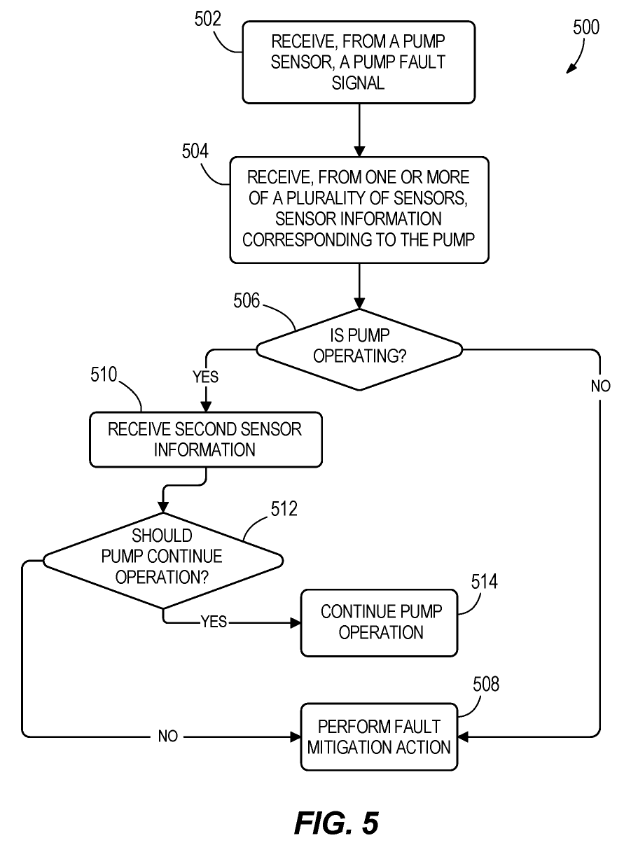

FIG. 5 is a flowchart of a method 500 for operating a component (for example, a pump) of the CDU 100 in accordance with some embodiments. Although the method 500 is described in conjunction with a pump of the CDU 100 as described herein, the method 500 could be used with other types of components of the CDU (for example, a valve of the plurality of valves 206). In addition, the method 500 may be modified or performed differently than the specific example provided. As an example, the method 500 is described as being performed by the electronic controller 300 and, in particular, the electronic processor 305. However, it should be understood that in some instances, portions of the method 500 may be performed by other devices or subsystems of the CDU 100. For ease of description, the method is described in terms of a single pump of the plurality of pumps 208 and a single first sensor and a second sensor. It should be understood, however, that the method 500 may be implemented for more than one component of the CDU 100 (for example, more than one pump of the pumps 208) and more than one of the first sensor and/or second sensor.

At block 502, the electronic processor 305 detects, based on first sensor information from a first sensor of the plurality of sensors 204, a (potential) fault of the component. The first sensor may be, for example, a pump sensor and the first sensor information may be a pump fault signal. At block 504, the electronic processor 305 receives, from a second sensor of the plurality of sensors 204, second sensor information corresponding to the component. In some embodiments, the second sensor information is from more than one sensor of the plurality of sensors 204. The second sensor information may be information from one or more sensors upstream of the component and/or the first sensor, downstream from the component and/or the first sensor, or both. As another example, the second sensor(s) may include particular sensors selected by the electronic controller 300 based on the particular component being analyzed (for example, based on the position of the component within the system 200). The second sensor information may be information from a common type of sensor (for example, temperature sensors, pressure sensors, etc.) or from more than one type of sensor. In some embodiments, the type of sensor(s) that provide the sensor information to the processor 305 is/are not the same type of sensor as the first sensor. For example, in some embodiments, the first sensor is a flow rate sensor and the one or more other sensors is/are pressure sensor(s).

At block 506, the electronic processor 305, based on the second sensor information, verifies whether the fault of the component is valid. For instance, if the pump 208 is not operating at block 506, the fault may be determined to be valid. In response to determining that the fault is valid, the electronic processor 305, at block 508, performs a fault mitigation action (for example, generate an alert to a user (for example, via the HMI 330), adjust an operation of one or more components of the CDU 100, etc.). If the electronic processor 305 determines at block 506 that the fault is not valid, the electronic processor 305 receives at block 510 the second sensor information. In other embodiments, the electronic processor may receive a third sensor information from another sensor of the plurality of sensors. The third sensor and the third sensor information may be the same as the second sensor and the second sensor information, respectively, or may be a different sensor and a different sensor information. In response to determining that the fault is not valid, the electronic processor 305 determines whether to continue to allow the component to operate (block 512), ignoring the first sensor formation (and detected potential fault) and continuing to operate the component (block 514), or to not allow the component to operate, and to perform a fault mitigation action (block 508). In some embodiments, the electronic processor 305, at block 508, is also configured to generate an alert to a user regarding a potential fault with the first sensor.

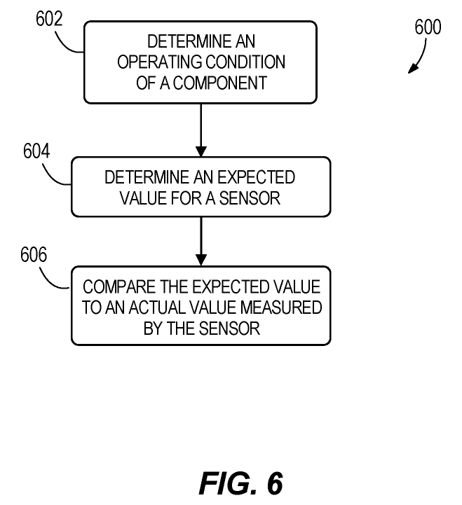

With reference to FIG. 6, in some embodiments, the controller 300 is configured to operate one or more of the pumps 208, valves 206, or both according to a feed-forward loop 600. The feed-forward loop method 600 is described as being performed by the electronic controller 300. However, it should be understood that in some instances, portions of the method 600 may be performed by other devices or subsystems of the CDU 100. For a given operation of one or more components of the system 200, the controller 300 may be configured to determine and/or set, at a first step 602, one or more operating conditions of a component. The operating condition may be, for instance, a desired operating condition, such as a desired flow rate, a desired coolant temperature, etc. For example, the controller 300 may be operating at pump at a speed of 60% of the maximum speed of the pump, which is the operation condition determined by the controller 300. At a second step 604, based on the operating conditions, the controller 300 is configured to determine one or more expected values/range of values for one or more sensors 204. For example, when operating a particular pump of the plurality of pumps 208 at a speed of 60% of a maximum speed of the pump, the controller 300 determines one or more expected values (for example, temperature, pressure, flow rate, etc.) for one or more of the plurality of sensors 204 (e.g., a temperature sensor, a pressure sensor, a flow rate sensor, etc.). The expected values may be predetermined and stored, for example, within the memory 310 (for example, within a look-up table), generated from one or more performance prediction models, or some combination thereof. At a third step 606, the controller 300 compares the expected value/range determined at step 604 with a measurement of a condition from a sensor 204. In some embodiments, the feed-forward loop may be utilized to more efficiently operate the CDU and/or to enhance optimization of energy consumption and reliability. For instance, the feed-forward loop may determine a desired operating condition at step 602 (e.g., a desired motor speed that may be energy-efficient), and then determine, based on that operating condition, an expected value, and compares the expected value with a condition measured by a sensor. In that process, the controller 300 is able to more accurately predict an operating condition measured by a sensor based on another desired condition. The controller 300 may also, in that way, operate at a desired operating condition instead of gradually increasing, for instance, a motor speed, to achieve the desired operating conditions, which would be quicker and more efficient. In following steps, the controller 300 may further refine the operating conditions (e.g., modify the pump speed) in order to change the measured operating conditions of the CDU 100.

As described above, erroneous fault detection may inhibit system performance of the CDU. Such false fault detections may be caused by inaccurate measurements and/or faulty sensors. Accordingly, it may be advantageous to verify measurements from a sensor by comparing measurements from multiple (redundant) sensors of a common type positioned within proximity of each other to determine if any are inaccurate. This may be beneficial for components with limited inputs for sensor measurements. For example, the VFD pump 208 may include a single input for receiving pressure measurements. In such instances, it may be important that the received measurement(s) are accurate.

In some embodiments, the electronic controller 300 (and components thereof) are disposed on a single circuit board.

What is claimed is:

1. A method of operating a component of a cooling distribution unit (CDU), the method comprising:
detecting, based on a first sensor information from a first sensor of a plurality of sensors of the CDU, a fault of a component;
receiving, from a second sensor of the plurality of sensors, a second sensor information corresponding to the component;
verifying, based on the second sensor information, whether the fault is valid; and
continuing an operation of the component, in response to determining that the fault is not valid.

2. The method of claim 1, wherein the first sensor and the second sensor are one of a temperature sensor, a pressure sensor, and a flow meter.

3. The method of claim 1, wherein the component is a pump.

4. The method of claim 1, wherein the component is a filter.

5. The method of claim 1, wherein the first sensor information and the second sensor information correspond to a temperature of a coolant.

6. The method of claim 1, wherein the first sensor information and the second sensor information correspond to a flow rate of a coolant.

7. The method of claim 1, wherein the first sensor information and the second sensor information correspond to a pressure of a coolant.

8. A method of controlling a coolant distribution unit (CDU), the method comprising:
determining an operating condition of a component of the CDU;
determining an expected value for a sensor configured to measure a condition of the component; and
comparing the expected value to an actual value measured by the sensor.

9. The method of claim 8, wherein the expected value is stored within a memory.

10. The method of claim 8, wherein the component is one of a pump and a valve.

11. The method of claim 8, wherein the operating condition is one of a flow rate, a temperature, or a pressure.

12. A coolant distribution unit comprising:
a fluid coolant flow system including one or more components;
a controller configured to control operation of the components; and
a first sensor configured to provide a first sensor information based on a first condition of the fluid coolant flow system, a second sensor configured to provide a second sensor information based on a second condition of the fluid coolant flow system, and a third sensor configured to provide a third sensor information based on a third condition of the fluid coolant flow system,
wherein the controller is configured to
determine a fault of the components based on the first sensor information or the second sensor information,
verify, based on another of the first sensor information and the second sensor information, whether the fault is valid, and
continue an operation of the components, in response to determining that the fault is not valid, and
determine an expected value for the third sensor based on an operating condition of one of the components, and
compare the expected value to the third sensor information.

13. The coolant distribution unit of claim 12, wherein the first sensor and the second sensor are one of a temperature sensor, a pressure sensor, and a flow meter.

14. The coolant distribution unit of claim 12, wherein the components include one of a pump and a filter.

15. The coolant distribution unit of claim 12, wherein the first sensor information and the second sensor information correspond to a temperature of a coolant.

16. The coolant distribution unit of claim 12, wherein the first sensor information and the second sensor information correspond to a flow rate of a coolant.

17. The coolant distribution unit of claim 12, wherein the first sensor information and the second sensor information correspond to a pressure of a coolant.

18. The coolant distribution unit of claim 12, wherein the third sensor is the same as the second sensor.

19. The coolant distribution unit of claim 12, wherein the expected value is stored within a memory.

20. The coolant distribution unit of claim 12, wherein the third sensor is one of a flow rate sensor, a pressure sensor, and a temperature sensor.
